(19) United States
(12) Patent Application Publication
(10) Pub. No.: US 2024/0170609 A1
(43) Pub. Date: May 23, 2024

(54) VERTICAL-TYPE LIGHT-EMITTING DIODE AND LIGHT-EMITTING DEVICE

(71) Applicant: Quanzhou sanan semiconductor technology Co., Ltd., Fujian (CN)

(72) Inventors: Yenchin WANG, Fujian (CN); Jinghua CHEN, Fujian (CN); Huanshao KUO, Fujian (CN); Yuren PENG, Fujian (CN)

(73) Assignee: Quanzhou sanan semiconductor technology Co., Ltd., Fujian (CN)

(21) Appl. No.: 18/509,159

(22) Filed: Nov. 14, 2023

(30) Foreign Application Priority Data
Nov. 21, 2022 (CN) 202211456774.6

(51) Int. Cl. H01L 33/08

(52) U.S. Cl. CPC H01L 33/08; H01L 33/32

(57) ABSTRACT

The disclosure relates to the field of semiconductor manufacturing technology, and in particular to a vertical-type light-emitting diode, which includes a substrate, a semiconductor stack layer and an insulation implant layer. The semiconductor stack layer is disposed on the substrate, and the semiconductor stack layer includes the first semiconductor layer, the light-emitting layer and the second semiconductor layer that are sequentially stacked on the substrate. The insulation implant layer is formed in the semiconductor stack layer to divide the semiconductor stack layer into at least two individual dies. By forming the insulation implant layer in the semiconductor stack layer, it is possible to achieve small spacing between dies and allow them to be insulated from each other without the need to create trenches or use PI adhesive. It is possible to ensure the photoelectric quality of the vertical-type light-emitting diodes and make the surface of the vertical-type light-emitting diodes flatter.

### CROSS-REFERENCE TO RELATED APPLICATION

This application claims the priority benefit of Chinese application serial no. 202211456774.6, filed on Nov. 21, 2022. The entirety of the above-mentioned patent application is hereby incorporated by reference herein and made a part of this specification.

### BACKGROUND

### Field of the Disclosure

The present disclosure relates to the field of semiconductor manufacturing technology, and in particular to a vertical-type light-emitting diode and a light-emitting device.

### Description of Related Art

Light-emitting diode (LED) is a semiconductor device that emits light, and generally made of semiconductors such as GaN, GaAs, GaP, GaAsP, etc. The core of LED is a PN junction with light-emitting properties. LED is characterized in advantages of high luminous intensity, high efficiency, small size, and long service life, and is considered to be one of the most promising light sources currently. LED has been commonly adopted in lighting, monitoring and commanding, high-definition videos, high-end cinema, office display, conference interaction, virtual reality and other fields.

Compared with other display technologies, micro LED display technology has high brightness, high contrast, high resolution, high reliability, long service life, low energy consumption and other advantages. Micro LED has high potential to be applied in watches, flexible screens, micro displays, and so on and is considered to be a new generation of light display technology.

At present, a chip required for AR is very small in size, and the spacing between dies is generally designed to be within 5 μm. LEDs are normally manufactured into vertical-type LEDs to achieve LEDs with a short spacing less than 5 μm in consideration of limitations and costs of current available process. The existing process for manufacturing vertical-type LEDs is mainly as follows: first, a wafer is bonded to a silicon substrate or silicon-CMOS, and then a chip manufacturing process is performed subsequently. With regard to the small spacing between dies, due to the large aspect ratio, there are many difficulties in performing dry etching. As for the height difference generated after etching, the climbing behavior of electrodes (transparent electrodes such as ITO, etc. are normally adopted) will occur and cause ITO to break.

As shown in FIG. 1A to FIG. 1F, some manufacturers currently adopt PI adhesive (adhesive polyimide tape) to fill the spacing between dies to solve the height difference problem after etching. However, since the PI adhesive has low resistance to heat, during the annealing treatment stage, the PI adhesive will be affected by high temperature and damage the surface of the dies. Therefore, there is still a certain degree of height difference generated on the surface, which affects the bridging of ITO and therefore it is not possible to make the whole surface shine (as shown in FIG. 2, the ITO in the area circled by two circles in dashed-line is at risk of breakage). Accordingly, the final photoelectric quality is impacted adversely.

It should be noted that the information disclosed in this background section is only intended to increase understanding of the general background of the present disclosure, and should not be regarded as an acknowledgement or in any way implying that the information constitutes what is already known to those of ordinary skill in the art.

### SUMMARY OF THE DISCLOSURE

The disclosure provides a vertical-type light-emitting diode, which includes a substrate, a semiconductor stack layer and an insulation implant layer.

The semiconductor stack layer is disposed on the substrate. The semiconductor stack layer includes a first semiconductor layer, a light-emitting layer and a second semiconductor layer that are sequentially stacked on the substrate. An insulation implant layer is formed in the semiconductor stack layer to divide the semiconductor stack layer into at least two individual dies.

In some embodiments, the insulation implant layer extends downwardly from an upper surface of the second semiconductor layer into the first semiconductor layer.

In some embodiments, the insulation implant layer is directly formed in the semiconductor stack layer by means of ion implantation.

In some embodiments, the material of the insulation implant layer includes hydrogen atoms (H atoms), argon atoms (Ar atoms), nitrogen atoms (N atoms) or helium atoms (He atoms).

In some embodiments, at least two individual dies are insulated from each other.

In some embodiments, each individual chiplet includes a first semiconductor layer, a light-emitting layer and a second semiconductor layer stacked in sequence.

In some embodiments, the spacing between two adjacent insulation implant layers is less than or equal to 5 μm.

In some embodiments, the width of the insulation implant layer is less than or equal to 2 μm.

In some embodiments, the thickness of the insulation implant layer ranges from 1.5 μm to 2 μm.

In some embodiments, the thickness of the semiconductor stack layer is less than or equal to 2 μm.

In some embodiments, the height difference of the upper surface of the vertical-type light-emitting diode is less than 0.5 μm.

In some embodiments, the vertical-type light-emitting diode further includes a first electrode and a second electrode. The first electrode is disposed between the semiconductor stack layer and the substrate, and the second electrode is disposed on one side of the semiconductor stack layer away from the substrate, wherein at least two individual dies share the first electrode and the second electrode to form a parallel connection structure.

In some embodiments, the second electrode adopts a transparent current spreading electrode and/or a metal electrode.

In some embodiments, the first semiconductor layer is an N-type semiconductor layer, the second semiconductor layer is a P-type semiconductor layer, the first electrode is a common cathode electrode, and the second electrode is a common anode electrode.

In some embodiments, the first semiconductor layer is a P-type semiconductor layer, the second semiconductor layer is an N-type semiconductor layer, the first electrode is a common anode electrode, and the second electrode is a common cathode electrode.

The present disclosure further provides a light-emitting device, which includes a circuit substrate and a vertical-type light-emitting diode. The vertical-type light-emitting diode is disposed on the circuit substrate. The vertical-type light-emitting diode may adopt vertical-type light-emitting diode provided in any of the above embodiments.

An embodiment of the present disclosure provides a vertical-type light-emitting diode and a light-emitting device. By forming an insulation implant layer in a semiconductor stack layer, it is possible to achieve small spacing between dies and allow them to be insulated from each other without the need to create trenches or use PI adhesive. In this way, it is possible to ensure the photoelectric quality of the vertical-type light-emitting diodes and make the surface of the vertical-type light-emitting diodes flatter.

Other features and advantageous effects of the present disclosure will be set forth in the subsequent description, and some of the technical features and advantageous effects may be apparent from the description or learned by practicing the present disclosure.

### BRIEF DESCRIPTION OF THE DRAWINGS

In order to more clearly explain the embodiments of the present disclosure or the technical solutions in the related art, a brief introduction will be provided below to the drawings that need to be used in the description of the embodiments or the related art. It is clear that some of the drawings in the following description illustrate some embodiments of the present disclosure. For those of ordinary skill in the art, other drawings can be obtained based on these drawings without exerting any creative effort.

FIG. 1A to FIG. 1F are schematic structural diagrams illustrating various stages of existing vertical-type LEDs.

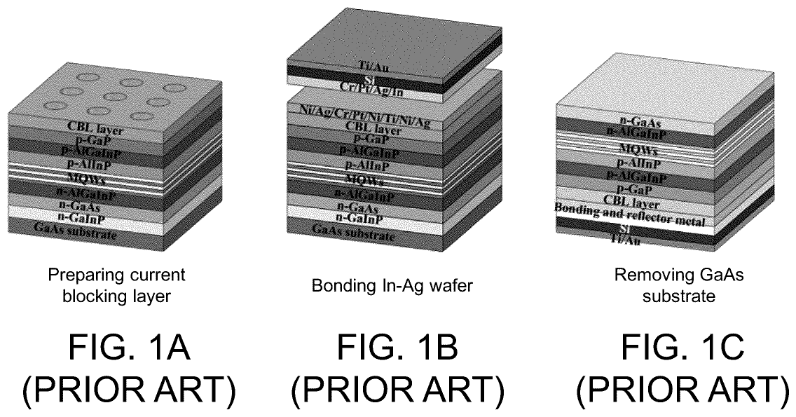

FIG. 2 is a schematic diagram illustrating breakage of ITO.

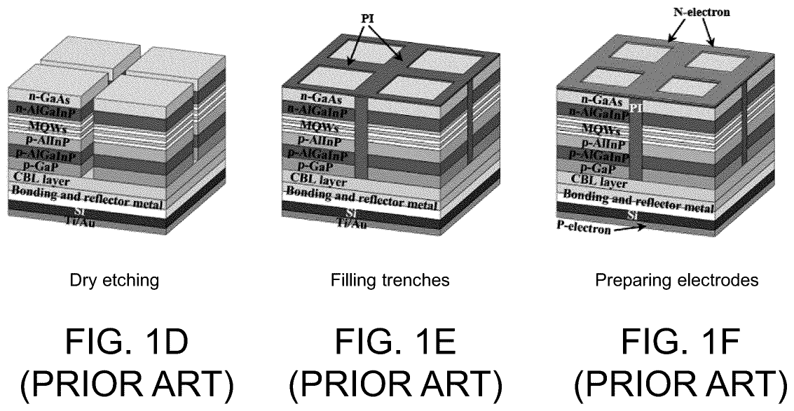

FIG. 3 is a schematic structural diagram illustrating a vertical-type light-emitting diode provided in an embodiment of the present disclosure.

FIG. 4 is a schematic diagram illustrating an ion implantation using N atoms.

FIG. 5 is a schematic diagram illustrating an ion implantation using H atoms.

FIG. 6 is a schematic structural diagram illustrating a vertical-type light-emitting diode provided in another embodiment of the present disclosure.

FIG. 7 to FIG. 9 are schematic structural diagrams illustrating various stages of the manufacturing process of the vertical-type light-emitting diode shown in FIG. 6.

### DESCRIPTION OF EMBODIMENTS

In order to make the purpose, technical solutions and advantages of the embodiments of the present disclosure clearer, the technical solutions in the embodiments of the present disclosure will be clearly and completely described below in conjunction with the drawings in the embodiments of the present disclosure. Clearly, the described embodiments are some embodiments of the present disclosure, not all of them; the technical features designed in different embodiments of the present disclosure described below may be combined with each other as long as they do not conflict with each other. Based on the embodiments of the present disclosure, all other embodiments obtained by those of ordinary skill in the art without creative efforts should fall within the scope to be protected by the present disclosure.

In the description of the present disclosure, it should be understood that the terms “center”, “lateral”, “upper”, “lower”, “left”, “right”, “vertical”, “horizontal”, “top”, “bottom”, “inner”, “outside”, etc. that indicate orientations or positional relationships are based on the orientations or positional relationships shown in the drawings. The above terms are only used for the convenience of describing the present disclosure and simplifying the description, and do not indicate or imply that the referred device or assembly must have a specific orientation, or be constructed and operate in a specific orientation and are therefore not to be construed as limitations of the disclosure. In addition, the terms “first” and “second” are used for descriptive purposes only and cannot be understood as indicating or implying relative importance or implicitly indicating the quantity of indicated technical features. Therefore, features defined as “first” and “second” may explicitly or implicitly include one or more of these features. In the description of the present disclosure, unless otherwise specified, “plurality” means two or more. In addition, the term “including” and any variations thereof mean “at least including”.

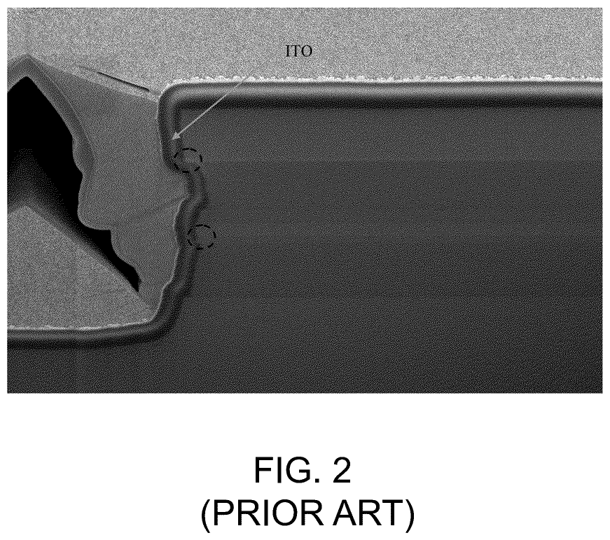

Please refer to FIG. 3, FIG. 3 is a schematic structural diagram illustrating a vertical-type light-emitting diode according to an embodiment of the present disclosure. An embodiment of the present disclosure provides a vertical-type light-emitting diode. As shown in the figure, the vertical-type light-emitting diode may include a substrate 10, a semiconductor stack layer 12 and an insulation implant layer 16.

The substrate 10 may be an insulation substrate. Preferably, the substrate 10 may be made of a transparent material or a semi-transparent material. In the illustrated embodiment, the substrate 10 is a sapphire substrate. In some embodiments, the substrate 10 may be a patterned sapphire substrate, but the disclosure is not limited thereto. The substrate 10 may also be made of a conductive material or a semiconductor material. For example, the material of the substrate 10 may include at least one of silicon carbide, silicon, magnesium aluminum oxide, magnesium oxide, lithium aluminum oxide, aluminum gallium oxide, and gallium nitride.

The semiconductor stack layer 12 is disposed on the substrate 10. The semiconductor stack layer 12 includes a first semiconductor layer 121, a light-emitting layer 122 and a second semiconductor layer 123 which are sequentially stacked on the substrate 10. That is to say, the first semiconductor layer 121 is located between the substrate 10 and the light-emitting layer 122, and the light-emitting layer 122 is located between the first semiconductor layer 121 and the second semiconductor layer 123.

The first semiconductor layer 121 may be an N-type semiconductor layer and may provide electrons to the light-emitting layer 122 under the action of a power source. In some embodiments, the first semiconductor layer 121 includes an N-type doped nitride layer, an arsenide layer, or a phosphide layer. The N-type doped nitride layer, arsenide layer, or phosphide layer may include one or more N-type impurities of Group IV elements. The N-type impurity may include one of Si, Te, Ge, Sn or a combination thereof. In some embodiments, a buffer layer may be disposed between the first semiconductor layer 121 and the substrate 10 to mitigate the lattice mismatch between the substrate 10 and the first semiconductor layer 121. The buffer layer may include an unintentionally doped GaN layer (undoped GaN, abbreviation: u-GaN) or an unintentionally doped AlGaN layer (undoped AlGaN, abbreviation: u-AlGaN). The first semiconductor layer 121 may also be connected to the substrate 10 through an adhesive layer.

The light-emitting layer 122 may have a quantum well structure (abbreviation: QW). In some embodiments, the light-emitting layer 122 may also be a multiple quantum well structure (abbreviation: MQW), wherein the multiple quantum well structure includes multiple quantum well layers and multiple quantum barrier layers that are alternately arranged in a repetitive manner, such as a multiple quantum well structure of GaInP/AlGaInP, AlGaInP/AlGaInP or InGaAs/AlGaAs. In addition, the constitution and thickness of the well layer within the light-emitting layer 122 determine the wavelength of the generated light. By changing the depth of the quantum wells, the number, thickness and/or other characteristics of the paired quantum well layers and quantum barrier layers in the light-emitting layer 122, it is possible to improve the light-emitting efficiency of the light-emitting layer 122.

The second semiconductor layer 123 may be a P-type semiconductor layer and may provide cavities to the light-emitting layer 122 under the action of power supply. In some embodiments, the second semiconductor layer 123 includes a P-type doped nitride layer, an arsenide layer, or a phosphide layer. The P-type doped nitride layer, the arsenide layer, or the phosphide layer may include one or more P-type impurities of Group II elements. The P-type impurities may include one of Mg. Zn, Be or a combination thereof. The second semiconductor layer 123 may be a single-layer structure or a multi-layer structure, and the multi-layer structure has different constitutions. In addition, the arrangement of the epitaxial structure is not limited thereto, and other types of epitaxial structures may be selected according to actual needs.

The insulation implant layer 16 is formed in the semiconductor stack layer 12 to divide the semiconductor stack layer 12 into at least two individual dies 14. The formed at least two individual dies 14 are insulated from each other (insulated from each other through the insulation implant layer 16). Each individual die 14 includes a first semiconductor layer 121, a light-emitting layer 122 and a second semiconductor layer 123 stacked in sequence, and the structure of each individual die 14 may be the same. The insulation implant layer 16 may be directly formed in the semiconductor stack layer 12 by means of ion implantation. For example, ions with insulation properties may be injected downwardly from the upper surface of the second semiconductor layer 123 until they are injected into the first semiconductor layer 123, which replaces the conventional trenching method to divide the semiconductor stack layer 12 into multiple individual dies 14. That is to say, by forming the insulation implant layer 16 in the semiconductor stack layer 12, there is no need to create a trench like a conventional vertical-type LED (without creating trenches, there is no need to use PI adhesive to fill the trenches), and it is possible to achieve small spacing between the dies 14 while they are able to be insulated from each other. Furthermore, it is possible to avoid the uneven surface of conventional vertical-type LEDs caused by opening trenches with high aspect ratios. Generally speaking, if the uneven surface has a height difference greater than 1 um, the risk of electrode breakage due to the height difference in climbing will affect the parallel connection results of the electrodes for each individual die 14. With this arrangement, the height difference of the upper surface of the vertical-type light-emitting diode structure may be less than 0.5 μm, that is, a vertical-type light-emitting diode structure with a flat surface may be obtained.

In some embodiments, the insulation implant layer 16 extends downwardly from the upper surface of the second semiconductor layer 123 into the first semiconductor layer 121, that is, the depth at which the insulation implant layer 16 extends downwardly exceeds the depth of the light-emitting layer 122, thereby achieving insulation. Generally speaking, if this ion implantation technology is not adopted, in order to reduce the height difference of the etched trench, the thickness H2 of the semiconductor stack layer 12 is generally set to be less than or equal to 2 μm. Preferably, the thickness H1 of the insulation implant layer 16 ranges from 1.5 μm to 2 μm. In the illustrated embodiment, the thickness of the insulation implant layer 16 is equal to the thickness of the semiconductor stack layer 12.

In some embodiments, the spacing W1 between two adjacent injection implant layers 16 is less than or equal to 5 μm, and the width W2 of the insulation implant layer 16 is less than or equal to 2 μm, thereby realizing a small spacing between the dies 14.

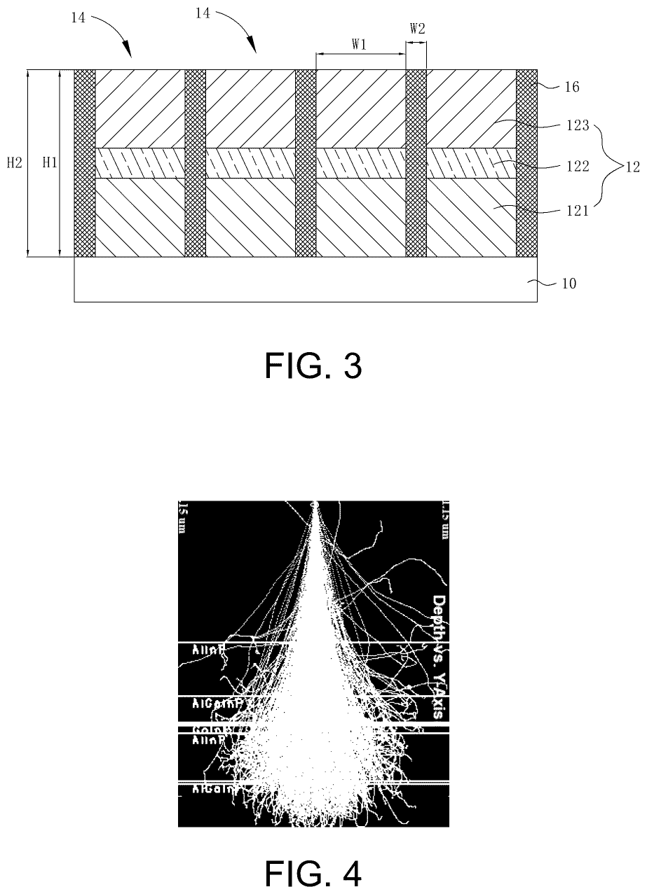

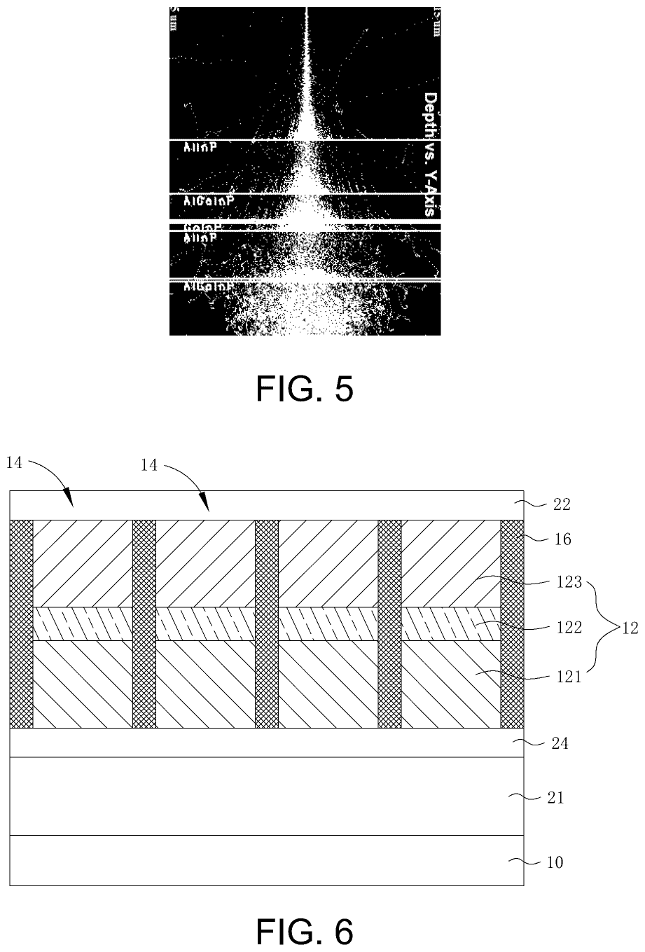

The material of the insulation implant layer 16 may include H atoms, Ar atoms, N atoms or He atoms, etc. As shown in FIG. 4 and FIG. 5, considering that the formed insulation implant layer 16 needs to extend beyond the light-emitting layer 122 and the diffusion width should be as small as possible, it is better to perform diffusion when the insulation implant layer 16 has reached a deep position. Comparing the conditions of using of H atoms and N atoms respectively, it can be seen that since the relative atomic mass H=1, N=14, the energy of the H atom is 250 keV and the energy of the N atom is 1600 keV, the greater the energy, the greater the width of the formed ion. Therefore, the N atom is used as the ion source for ion implantation, and the effect of the formed insulation implant layer 16 is relatively poor. Preferably, in ion implantation, ion sources with smaller atomic weights, such as H atoms and He atoms, are selected.

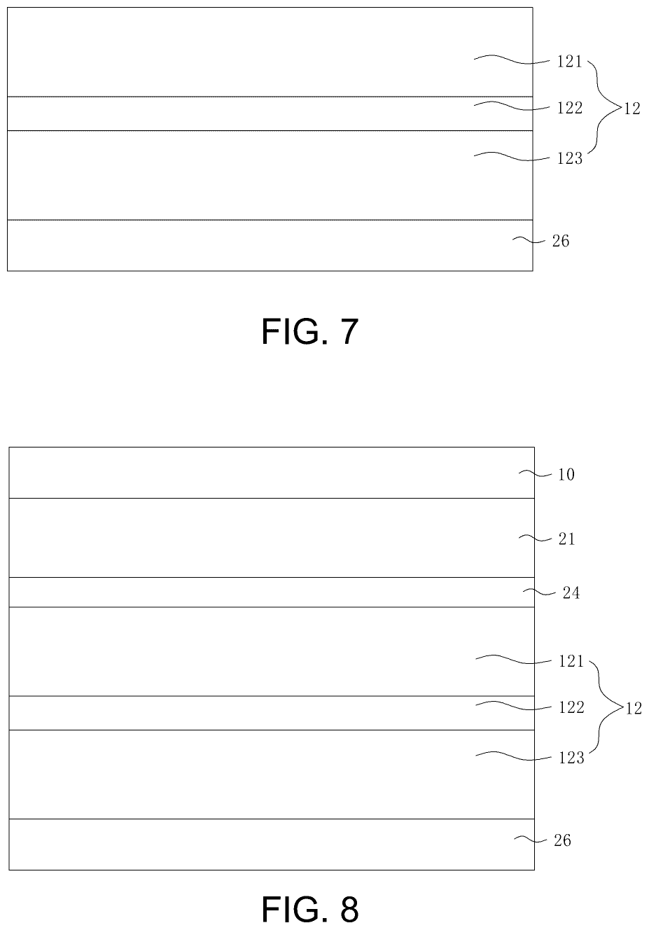

Please refer to FIG. 6, FIG. 6 is a schematic structural diagram illustrating a vertical-type light-emitting diode provided in another embodiment of the present disclosure. Compared with the vertical-type light-emitting diode shown in FIG. 3, the vertical-type light-emitting diode of this embodiment may further include a first electrode 21 and a second electrode 22.

The first electrode 21 is located between the semiconductor stack layer 12 and the substrate 10, and the first electrode 21 is electrically connected to the first semiconductor layer 121. The first electrode 21 may have a single-layer, double-layer or multi-layer structure like a stacked structure such as Ti/Al, Ti/Al/Ti/Au, Ti/Al/Ni/Au, V/Al/Pt/Au, etc.

The second electrode 22 is located on one side of the semiconductor stack layer 12 away from the substrate 10. The second electrode 22 is electrically connected to the second semiconductor layer 123 and forms a good ohmic contact with the second semiconductor layer 123. The second electrode 22 may adopt a transparent current spreading electrode and/or a metal electrode. For example, the second electrode 22 may adopt a transparent current spreading electrode, a metal electrode, or both a transparent current spreading electrode and a metal electrode. The surface of the second electrode 22 disposed above the second semiconductor layer 123 is also flat, and the height difference of the upper surface of the second electrode 22 (a surface away from the second semiconductor layer 123) is less than 0.5 μm.

In the vertical-type light-emitting diode, multiple individual dies 14 share the first electrode 21 and the second electrode 22, thus forming a parallel connection structure, that is, the multiple individual dies 14 are in a parallel connection relationship. In some embodiments, the first semiconductor layer 121 is an N-type semiconductor layer, the second semiconductor layer 123 is a P-type semiconductor layer, the first electrode 21 is a common cathode electrode, and the second electrode 22 is a common anode electrode. This kind of vertical-type light-emitting diode is more suitable for environments with large currents, and achieves a better photoelectric quality in environments with large currents. However, the present disclosure is not limited thereto. In other embodiments, the first semiconductor layer 121 may also be a P-type semiconductor layer, the second semiconductor layer 123 may be an N-type semiconductor layer, the first electrode 21 may be a common anode electrode, and the second electrode 22 may be a common cathode electrode. This kind of vertical-type light-emitting diode is more suitable for environments with small currents, and achieves a better photoelectric quality in environments with small currents.

In some embodiments, the vertical-type light emitting diode may further include a metal reflective electrode 24. The metal reflective electrode 24 is located between the first electrode 21 and the semiconductor stack layer 12 and is provided to reflect the light emitted by the light-emitting layer 122. In some embodiments, the first semiconductor layer 121 is an N-type semiconductor, and the metal reflective electrode 24 may be a metal structure of the AuGe series. If the first semiconductor layer 121 is a P-type semiconductor, the metal reflective electrode 24 may be a metal structure of the AuZn series or the BeAu series or an ITO transparent electrode structure. The metal reflective electrode 24 forms ohmic contact with the first semiconductor layer 121, and the first electrode 21 serves as a metal bonding layer of the substrate 10.

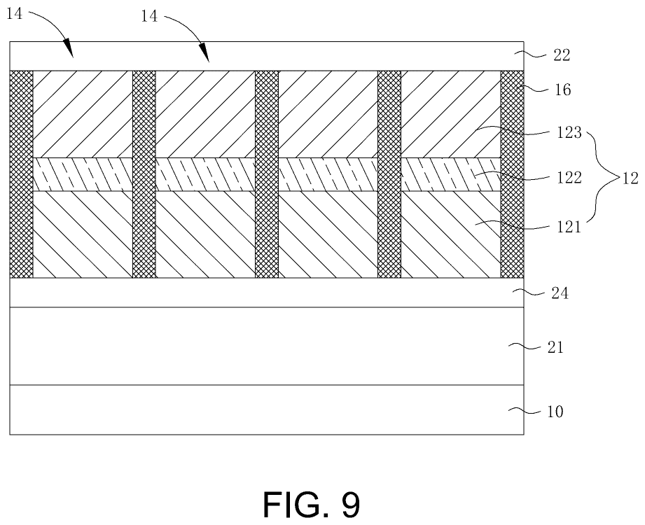

The following discloses a method for manufacturing the vertical-type light-emitting diode shown in FIG. 3. Please refer to FIG. 7 to FIG. 9. FIG. 7 to FIG. 9 are schematic structural diagrams illustrating various stages of the manufacturing process of the vertical-type light-emitting diode shown in FIG. 6.

First, as shown in FIG. 7, a growth substrate 26 is provided. Then, the second semiconductor layer 123, the light-emitting layer 122 and the first semiconductor layer 121 are sequentially grown on the growth substrate 26.

Next, as shown in FIG. 8, a metal reflective electrode 24 is formed on the first semiconductor layer 121. This metal reflective electrode 24 not only functions for metal reflection but also serves an ohmic contact function. Then, the first electrode 21 is adopted to connect with the substrate 10.

Finally, as shown in FIG. 9, the growth substrate 26 is removed first, and then a flip operation is performed. An ion implantation process is performed downward from the top of the second semiconductor layer 123 to form the insulation implant layer 16. The formed insulation implant layer 16 divides the semiconductor stack layer 12 into multiple individual dies 14. The second electrode 22 is then formed on the semiconductor stack layer 12 with the insulation implant layer 16.

The above embodiment only describes a method for manufacturing the vertical-type light-emitting diode shown in FIG. 3. This disclosure is not limited thereto, and the above embodiment is only used to illustrate a preparation and implementation method of the vertical-type light-emitting diode.

In some embodiments, a light-emitting device is provided. The light-emitting device includes a circuit substrate and a vertical-type light-emitting diode. The vertical-type light-emitting diode is disposed on the circuit substrate. The vertical-type light-emitting diode may be selected from the vertical-type light-emitting diodes described in any one of the above embodiments.

It should be noted that the structural characteristics of the ion implant layer may be obtained from vertical-type light-emitting diodes using OM, SEM, FIB or TEM and other methods.

To sum up, in the vertical-type light-emitting diode and light-emitting device provided in an embodiment of the present disclosure, by forming the insulation implant layer 16 in the semiconductor stack layer 12, it is possible to achieve small spacing between the dies 14 and keep them insulated from each other without having to create trenches and use PI adhesive. In this way, it is possible to ensure the photoelectric quality of the vertical-type light-emitting diode and make the surface of the vertical-type light-emitting diode flatter.

In addition, those skilled in the art should understand that although there are many problems in the related art, improvement may be made to only one or several aspects of each embodiment or technical solution of the present disclosure without having to simultaneously solve all of the problems listed in the existing technology or background technology. Those skilled in the art will understand that content not mentioned in a claim shall not be construed as a limitation to the claim.

Finally, it should be noted that the above embodiments are only used to illustrate the technical solution of the present disclosure, but not to limit the disclosure. Although the present disclosure has been described in detail with reference to the foregoing embodiments, those of ordinary skill in the art should understand that: The technical solutions described in the foregoing embodiments can still be modified, or some or all of the technical features can be equivalently replaced; and these modifications or replacement do not deviate the essence of the corresponding technical solutions from the scope of the technical solutions to be protected by the embodiments of the present disclosure.

What is claimed is:

1. A vertical-type light-emitting diode, comprising:
a substrate;
a semiconductor stack layer disposed on the substrate, wherein the semiconductor stack layer comprises a first semiconductor layer, a light-emitting layer and a second semiconductor layer that are sequentially stacked on the substrate;
an insulation implant layer formed in the semiconductor stack layer to divide the semiconductor stack layer into at least two individual dies.

2. The vertical-type light-emitting diode according to claim 1, wherein the insulation implant layer extends downwardly from an upper surface of the second semiconductor layer into the first semiconductor layer.

3. The vertical-type light-emitting diode according to claim 1, wherein the insulation implant layer is directly formed in the semiconductor stack layer by means of ion implantation.

4. The vertical-type light-emitting diode according to claim 1, wherein a material of the insulation implant layer comprises hydrogen atoms, argon atoms, nitrogen atoms or helium atoms.

5. The vertical-type light-emitting diode according to claim 1, wherein the at least two individual dies are insulated from each other.

6. The vertical-type light-emitting diode according to claim 1, wherein each of the individual dies comprises the first semiconductor layer, the light-emitting layer and the second semiconductor layer stacked in sequence.

7. The vertical-type light-emitting diode according to claim 1, wherein a spacing between two of the adjacent insulation implant layers is less than or equal to 5 μm.

8. The vertical-type light-emitting diode according to claim 1, wherein a width of the insulation implant layer is less than or equal to 2 μm.

9. The vertical-type light-emitting diode according to claim 1, wherein a thickness of the insulation implant layer ranges from 1.5 μm to 2 μm.

10. The vertical-type light-emitting diode according to claim 1, wherein a thickness of the semiconductor stack layer is less than or equal to 2 μm.

11. The vertical-type light-emitting diode according to claim 1, wherein a height difference of an upper surface of the vertical-type light-emitting diode is less than 0.5 μm.

12. The vertical-type light-emitting diode according to claim 1, wherein the vertical-type light-emitting diode further comprises a first electrode and a second electrode, the first electrode is disposed between the semiconductor stack layer and the substrate, and the second electrode is disposed on one side of the semiconductor stack layer away from the substrate, wherein the at least two individual dies share the first electrode and the second electrode to form a parallel connection structure.

13. The vertical-type light-emitting diode according to claim 12, wherein the second electrode adopts a transparent current spreading electrode and/or a metal electrode.

14. The vertical-type light-emitting diode according to claim 12, wherein the first semiconductor layer is an N-type semiconductor layer, the second semiconductor layer is a P-type semiconductor layer, the first electrode is a common cathode electrode, and the second electrode is a common anode electrode.

15. The vertical-type light-emitting diode according to claim 12, wherein the first semiconductor layer is a P-type semiconductor layer, the second semiconductor layer is an N-type semiconductor layer, the first electrode is a common anode electrode, and the second electrode is a common cathode electrode.

16. A light-emitting device, comprising: a circuit substrate and a vertical-type light-emitting diode, wherein the vertical-type light-emitting diode is disposed on the circuit substrate, and the vertical-type light-emitting diode adopts the vertical-type light-emitting diode according to claim 1.
